(19) United States
(12) Patent Application Publication
(10) Pub. No.: US 2011/0186975 A1
(43) Pub. Date: Aug. 4, 2011

(54) SEMICONDUCTOR PACKAGE AND MANUFACTURING METHOD THEREOF

(75) Inventor: CHIH-MING CHEN, Hukou (TW)

(73) Assignee: ADVANCED OPTOELECTRONIC TECHNOLOGY, INC., Hsinchu Hsien (TW)

(21) Appl. No.: 12/949,797

(22) Filed: Nov. 19, 2010

(30) Foreign Application Priority Data
Jan. 29, 2010 (TW) 99102578

(51) Int. Cl. H01L 23/495; H01L 21/56

(52) U.S. Cl. 257/676; 438/116; 257/E23.044; 257/E21.502

(57) ABSTRACT

A semiconductor package includes a substrate with a first surface and an opposite second surface, a plurality of metal rods throughout the first surface and the second surface of the substrate, a reflector surrounding the first surface of the substrate to form a functional area, a glass reflection layer covering the surfaces of reflector and the functional area and exposing a part of a first electrode area and a part of a second electrode area, at least one semiconductor chip adhered on the functional area, and a transparent gel covering the at least one semiconductor chip.

### BACKGROUND

1. Technical Field

The present disclosure relates generally to semiconductor technology, and more particularly to a semiconductor package.

2. Description of the Related Art

LEDs are extensively applied to illumination devices due to high brightness, low working voltage, low power consumption, compatibility with integrated circuitry, simple driving operation, long lifetime and other factors.

LEDs have replaced incandescent lamps in many interior and outdoor illuminations, such as Christmas decorations, display window decorations, interior lamps, landscaping, streetlamps and traffic signs. As such, LEDs are deployed in various conditions. However, some conditions may be too harsh for the related LED package, and thereby decrease the lifetime thereof.

Therefore, it is desirable to provide an LED package which can overcome the described limitations.

### BRIEF DESCRIPTION OF THE DRAWINGS

FIG. 1 is a flowchart showing a method for manufacturing a housing of a semiconductor package of the present disclosure.

FIG. 2˜FIG. 11 are cross-sections showing a method for manufacturing the package of the present disclosure, in which FIG. 11 shows a completed semiconductor package of the present disclosure.

### DETAILED DESCRIPTION

Referring to FIG. 11, a semiconductor package 200 of the present disclosure includes a substrate 206, a plurality of through holes 208, a reflector 224, a reflection layer 226, and at least one semiconductor chip 234. The substrate 206 has a first surface 210 and a second surface 212 opposite to the first surface 210, wherein the substrate 206 is aluminum oxide substrate, aluminum nitride substrate, or a stack of ceramic layers. The plurality of through holes 208 passes through the first surface 210 and the second surface 212 of the substrate 206, wherein the plurality of through holes 208 are filled by metal material 214 to form a plurality of metal rods, such as silver (Ag), nickel (Ni), copper (Cu), stannum (Sn), aluminum (Al), or a combination thereof. The reflector 224 surrounds the first surface 210 of the substrate 206 to form a functional area 232. A reflection layer 226 covers the surface of the reflector 224 and the surface of the functional area 232 exposing a part of a first electrode area 228 and a part of second electrode area 230, wherein the reflection layer 224 is a mixture of silicon oxide, boron oxide and magnesium oxide. Specifically, the reflection layer 224 is a glass layer. A metal layer includes a first conductive area 216 and a second conductive area 218 between the reflector 224 and the substrate 206. At least one semiconductor chip 234 is fixed on the surface of the functional area 232 by epoxy and connected electrically to the part of the first electrode area 228 and the second electrode area 230 by metal wires 236, wherein the metal wires 236 are gold wires and the semiconductor chip 234 can be a light emitting diode, a laser diode, or light sensing chip. In the preferred embodiment, the semiconductor chip 234 is a light emitting diode. Furthermore, a transparent gel 238 can be epoxy or silicone to cover at least the semiconductor chip 234, wherein the transparent gel 238 can also be doped with fluorescent converting material 240 to generate yellow light or other color light excited by the semiconductor chip 234. The fluorescent converting material 240 can be yttrium aluminum garnet (YAG), Terbium aluminum garnet (TAG), sulfide, phosphate, or oxynitride, Silicate. The mixture of the excited yellow light of the fluorescent converting material 240 and the light generated by the semiconductor 234 can be white light, whereby the semiconductor package 200 is a white light LED semiconductor package.

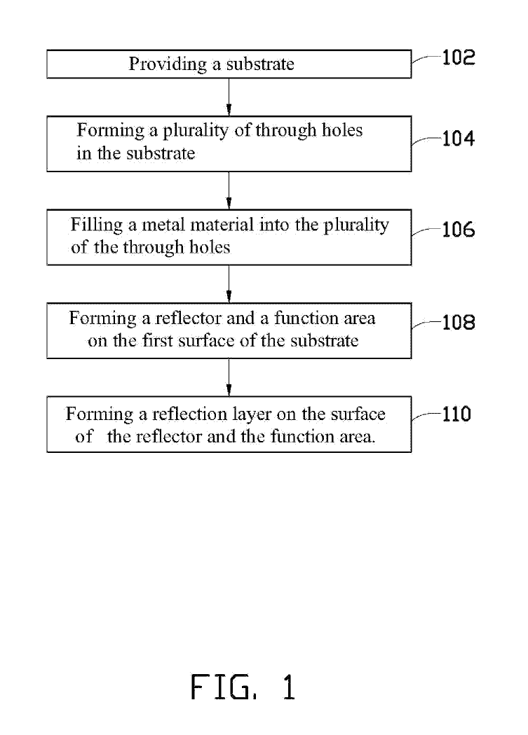

FIG. 1 is a flowchart showing a method for manufacturing a housing of the semiconductor package of the present disclosure. In step 102, a substrate is provided, which is the substrate 206 of FIG. 11. The substrate 206 can be an electrically insulating substrate, such as aluminum nitride substrate or aluminum oxide substrate.

In step 104 a plurality of through holes, which is the through holes 208 of FIG. 11 is formed in the substrate 206. The plurality of through holes 208 passes through a first surface (i.e. the first surface 210 of FIG. 11) and a second surface (i.e., the second surface 212 of FIG. 11) of the substrate 206 by laser or machine drilling.

In step 106 a metal material is filled into the plurality of the through holes 208. The metal material is the metal material 214 of FIG. 11. The metal material 214 not only can connect electrically to the first surface 210 and the second surface 212 of the substrate 206, but also dissipate heat generated by the semiconductor chip 234. The metal material 214 can be silver (Ag), nickel (Ni), copper (Cu), stannum (Sn), aluminum (Al), or a combination thereof.

In step 108 a reflector and a functional area on the first surface 210 of the substrate 206 are formed. The reflector and the functional area are the reflector 224 and the functional area 232 of FIG. 11. The reflector 224 surrounds the first surface 210 to form the functional area 232.

In step 110 a reflection layer is formed on the surfaces of the reflector 224 and of the functional area 232. By sintering, the surfaces of the substrate 206 and of the reflector 224 are roughened, causing the emitted light from the semiconductor chip 234 to scatter or diffuse to decrease the brightness of the package 200.

As disclosed, the reflection layer preferably is a glass reflection layer which is disposed on the surfaces of the reflector 224 and of the functional area 232, and a part of a first electrode area and a part of a second electrode area to be connected electrically are exposed. The reflection layer is the reflection layer 226 of FIG. 11. The first and second electrode areas are the first and second electrode areas 228, 230 of FIG. 11. Additionally, a first metal pad 220 and a second metal pad 222 (referring to FIGS. 6 and 11) are formed on the second surface 212 of the substrate 206 opposite the reflector 224. The first and second metal pads 220, 222 are used for electrically connecting the package 200 to an external power source. Accordingly the housing of the package 200 is completed.

The housing of the package 200 is disposed in a chamber at about 900° C. to sinter by low temperature cofired ceramics (LTCC) technology. The glass reflection layer 226 can be silicon oxide (SiO₂), boron oxide (B₂O₃), magnesium oxide (MgO), or a combination thereof. Superior glass properties such as higher gloss and transparency, stronger mechanical properties, better stability of thermal tolerance, insulating ability, and chemical properties, recommend it for advanced chemical instruments and insulating materials. As the reasons mentioned, the glass reflection layer 226 has smaller pore holes, leaving the surface of the reflection layer smoother to improve scattering and diffusion, and uniformly distributing heat for faster dissipation. The housing of the package 200 disclosed can enhance light brightness.

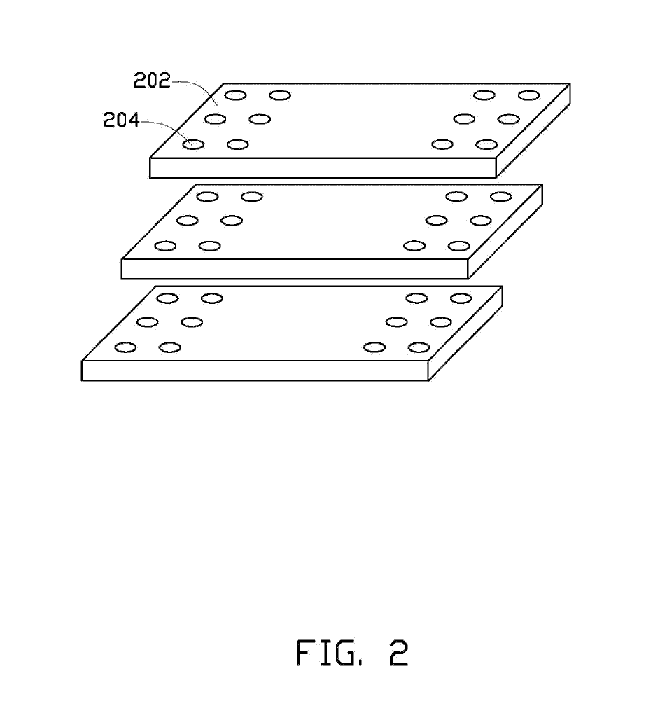

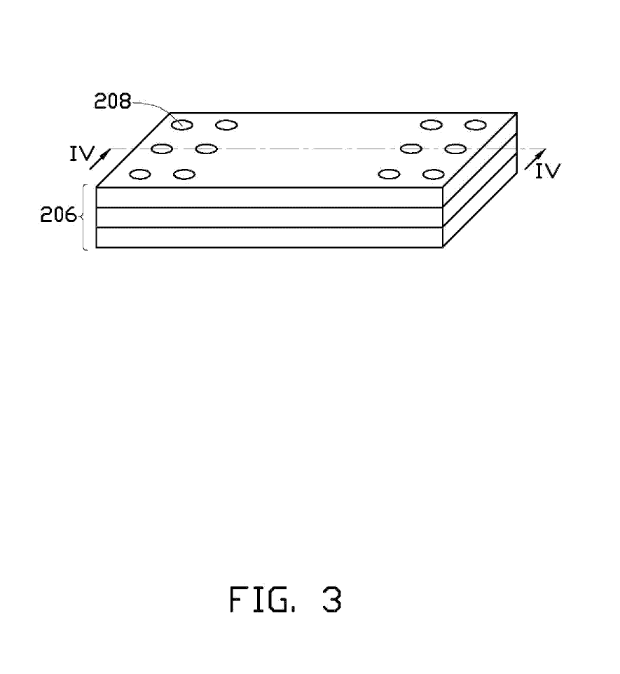

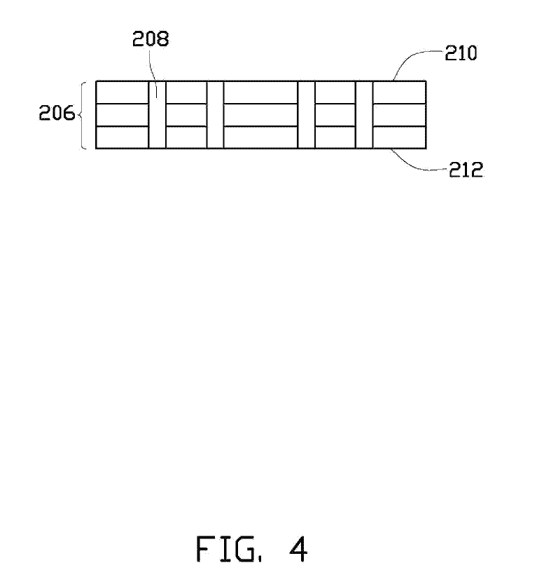

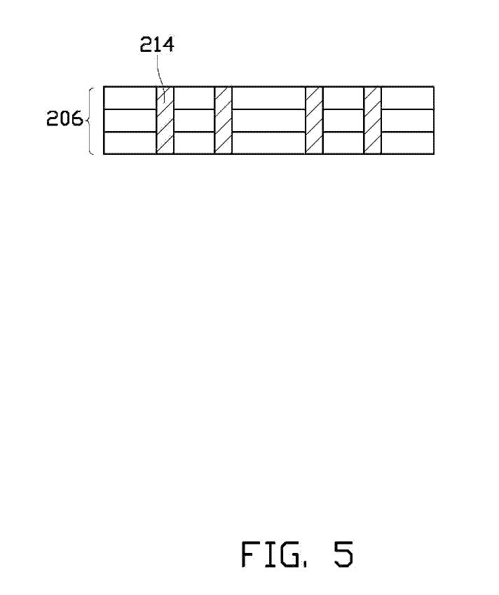

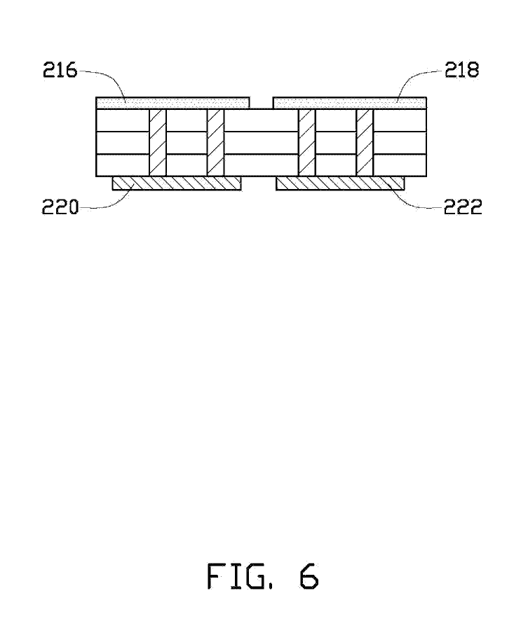

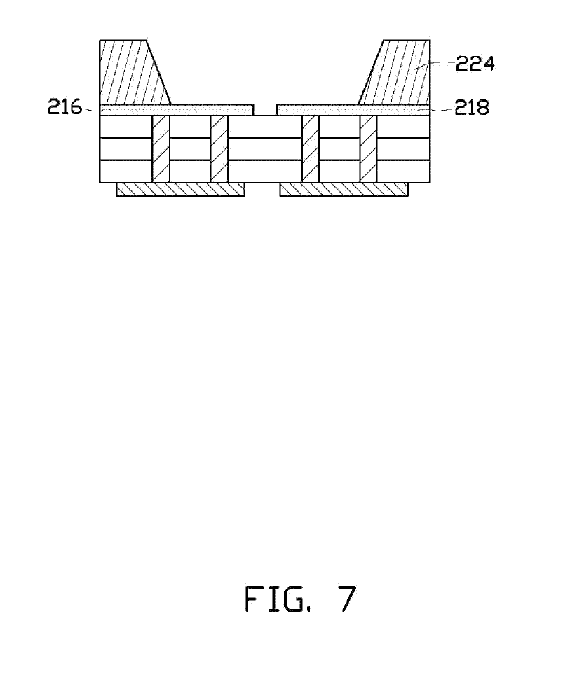

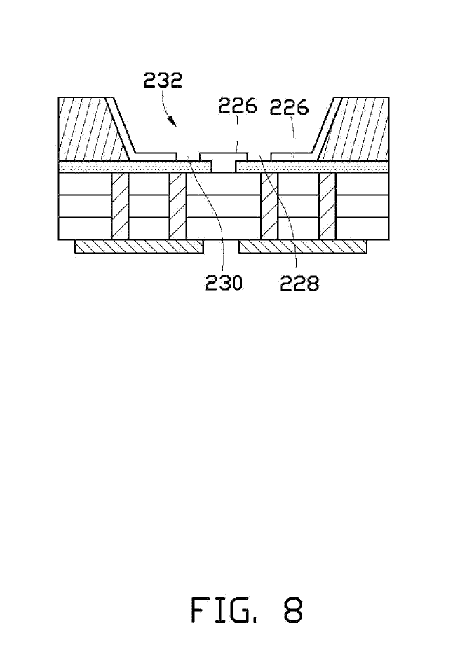

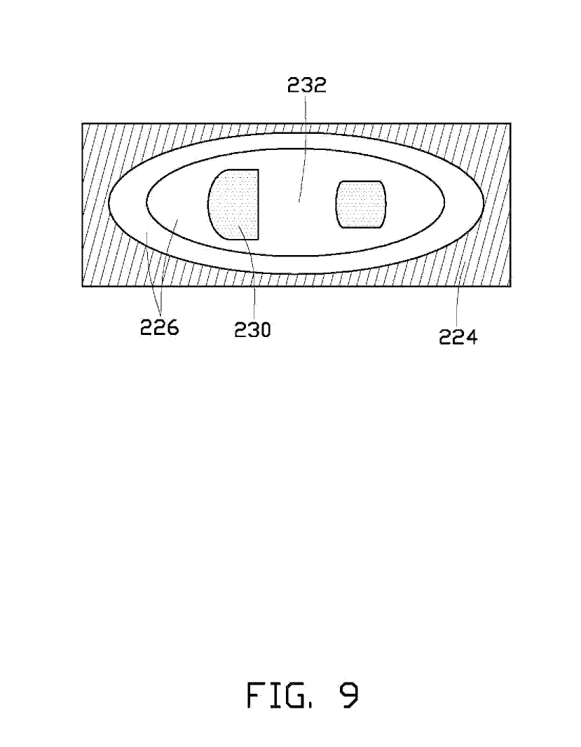

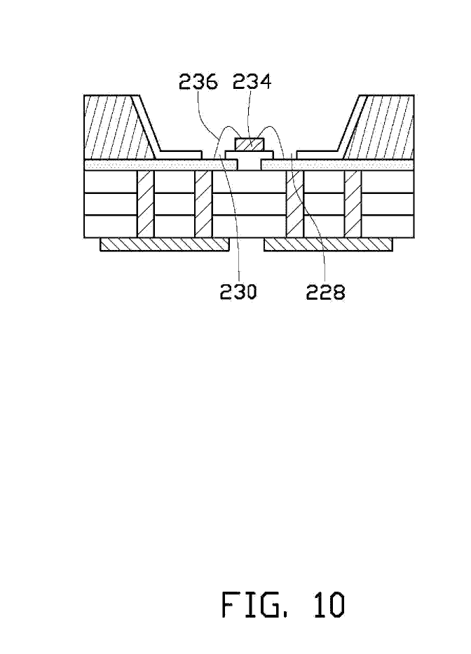

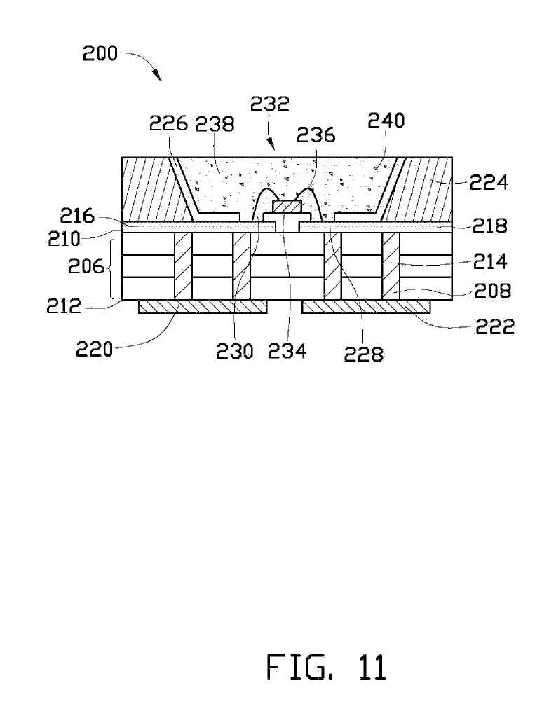

FIG. 2 to FIG. 11 are cross-sections of the method for manufacturing the semiconductor package 200 of the present disclosure. FIG. 2 shows a plurality of ceramic layers 202 with a plurality of holes 204 provided. FIG. 3 shows the ceramic layers 202 stacked together to form the substrate 206, wherein the plurality of holes 204 in the ceramic layer 202 correspond to each other to form the plurality of through holes 208. It can be further understood by a crossing line A to A′ on FIG. 3 and shows as FIG. 4, wherein the plurality of through holes 208 pass through the first surface 210 of the substrate 206 and the second surface 212 opposite to the first surface 210 on the substrate 206.

FIG. 5 shows the metal material 214 filled into the plurality of through holes 208 connecting electrically but also dissipating heat from the first surface 210 to the second surface 212 of the substrate 206. FIG. 6 shows a metal layer formed on the first surface 210 of the substrate 206, wherein the metal layer includes the first conductive area 216 and the second conductive area 218. The metal layer is silver. Additionally, the first metal pad 220 and the second metal pad 222 are formed on the second surface 212 of the substrate 206 opposite the first surface 210 of the substrate 206.

FIG. 7 and FIG. 8 show the reflector 224 on the first conductive area 216 and the second conductive area 218. A glass reflection layer 226 covers the surface of the reflector 224, the first conductive area 216 and the second conductive area 218, and exposes a first electrode area 228 and a second electrode area 230 for electrical connection An area surrounded by reflector 224 on the first conductive area 216 and the second conductive area 218 is referred to as the functional area 232. Next, FIG. 9 as top view shows the reflector 224 is surrounding to form the functional area 232. The glass reflection layer 226 covers the surface of the reflector 224 and of the functional area 232, and exposes the first electrode area 228 and the second electrode area 230.

FIG. 10 shows the semiconductor chip 234 fixed on the functional area 232 by epoxy and connected electrically to the first electrode area 228 and the second electrode area 230 by metal wires 236. The metal wires 236 can be gold. The semiconductor chip 234 can be light emitting diode, laser diode or light sensing chip.

Next, FIG. 11 shows the semiconductor chip 234 is covered by the transparent gel 238, such as epoxy or silicone, for reducing the damages of chip 234 from the environment pollution or moisture. Additionally, the transparent gel 238 also can be doped with the fluorescent converting material 240 to generate the yellow light or other color lights excited by the semiconductor chip 234. The fluorescent converting material 240 can be yttrium aluminum garnet (YAG), terbium aluminum garnet (TAG), sulfide, phosphate, oxynitride, or silicate.

Another embodiment uses a bulk substrate, such as aluminum oxide substrate or aluminum nitride substrate, instead of stacking substrate.

As the above mentioned, the present disclosure has many advantages. First at all, the plurality of through holes includes metal material which not only can be electrically conducting but also can be thermally conducting for enhancing the thermal dissipation of package. Secondary, the pore holes of the glass reflection layer are smaller than of the substrate and of the reflector. As the result, the surface of reflection layer is smoother to decrease the scattering and the diffusion and increase the brightness of package. Third, the one of properties of the glass is uniformly distributing thermal. When the thermal is generated by the semiconductor chip and dissipated through the glass reflection layer of the functional area uniformly distributing simultaneously. Then, the thermal is discharged from the substrate. Consequently, the package can be enhanced the lifespan of usage. Fourth, the glass reflection layer is substituted for the metal reflection layer to avoid the metal oxide generated to cause the brightness of the package decreased. Fifth, the glass reflection layer also can avoid the short circuit with the electrodes.

What is claimed is:

1. A semiconductor package comprising:
a substrate having a first surface and a second surface opposite to the first surface;
a plurality of metal rods throughout the first surface and the second surface of the substrate;
a reflector surrounding on the first surface of the substrate to form a functional area;
a reflection layer covering the surface of reflector and of the functional area, and exposing a part of a first electrode area and a part of a second electrode area, wherein the first electrode area and the second electrode area are connected to the metal rods;
at least one semiconductor chip adhered on the functional area and electrically connected to the exposed part of the first electrode area and the exposed part of the second electrode area;
a transparent gel covering at least the semiconductor chip, wherein the reflection layer is non-conductive material that is different material from the reflector, and pore holes on the reflection layer are smaller than those of the reflector and of the substrate.

2. The semiconductor package as claimed in claim 1, wherein the first and second electrode areas are formed by a metal layer formed between the substrate and the reflector.

3. The semiconductor package as claimed in claim 2, wherein the metal layer includes a first conductive area forming the first electrode area and a second conductive area forming the second electrode area.

4. The semiconductor package as claimed in claim 1, wherein the substrate is aluminum oxide substrate, aluminum nitride substrate, or a stack of ceramic layers.

5. The semiconductor package as claimed in claim 1, wherein the refection layer is a mixture of silicon oxide, boron oxide and magnesium oxide.

6. The package of compound semiconductor as claimed in claim 1, wherein the metal rods are silver (Ag), nickel (Ni), copper (Cu), stannum (Sn), aluminum (Al), or combination thereof.

7. A method of manufacturing a semiconductor package, comprising:
providing a substrate having a first surface and a second surface opposite the first surface;
forming a plurality of through holes throughout the first surface and the second surface opposite the first surface of the substrate;
filling metal material in the plurality of through holes to form metal rods;
disposing a reflector on the first surface of the substrate to form a functional area;
forming a reflection layer on the surface the reflector and of the functional area, and exposing a first electrode area and a second electrode area, wherein the first electrode area and the second electrode area are connected to the metal rods;
adhering at least one semiconductor chip on the functional area, and the semiconductor chip connected electrically to the first electrode area and the second electrode area; and
covering a transparent gel on at least the semiconductor chip, wherein the reflection layer is non-conductive material that is different material from the reflector, and the pore holes of the reflection layer are smaller than those of the reflector and of the substrate.

8. The method of manufacturing semiconductor package as claimed in claim 7, wherein the first and second electrode areas are formed by a metal layer between the reflector and the substrate.

9. The method of manufacturing semiconductor package as claimed in claim 7, wherein the metal layer includes a first conductive area for forming the first electrode area and a second conductive area for forming the second electrode area.

10. The method of manufacturing semiconductor package as claimed in claim 7 further comprising a first metal pad and a second metal pad on the second surface of the substrate.
